(19) United States
(12) Patent Application Publication
(10) Pub. No.: US 2023/0401481 A1
(43) Pub. Date: Dec. 14, 2023

(54) INTELLIGENT ELECTRONIC DEVICE AND METHOD THEREOF

(71) Applicant: Accuenergy (Canada) Inc., Toronto (CA)

(72) Inventors: Shaohang Cui, Toronto (CA); Ketao Li, Toronto (CA); Haoliang Deng, Toronto (CA); Yufan Wang, Toronto (CA); Liang Wang, Toronto (CA)

(21) Appl. No.: 17/836,144

(22) Filed: Jun. 9, 2022

(51) Int. Cl. G06N 20/00

(52) U.S. Cl. CPC G06N 20/00

(57) ABSTRACT

Provided are a method and apparatus to measure line frequency. Specifically, an Intelligent Electronic Device employs a method in which a processor receives a training dataset including an input variable set and a corresponding zero-crossing position output variable, obtains a hypothesis function based on the training dataset, estimates zero-crossing positions using the hypothesis function and computes a fundamental frequency of the signal based on the estimated zero-crossing positions.

### FIELD OF THE INVENTION

The present disclosure generally relates to the field of Intelligent Electronic Devices for electrical utility services and, more specifically, to digital electrical power and energy meters for use in performing electrical utility services.

### BACKGROUND

Monitoring electrical energy is a fundamental function within any electrical power distribution system. Electrical energy may be monitored to determine usage and power quality. A device that monitors electrical energy may be an Intelligent Electronic Device.

Line frequency is an essential index of power quality. An unexpected line frequency can result in maloperation or failure of customer equipment. In an Intelligent Electronic Device, conventional power line frequency measurement may use technical means, such as zero-crossing, digital Fourier Transform, phase-locked loop, or other methods to measure the frequency of electrical signals. However, monitored signals are subject to errors due to noise on the signals. Noise may be the result of various phenomena, including other equipment or loads on the electrical service, power generation equipment, or nearby electromagnetic radiation. Noise can affect the accuracy of line frequency measurement in an Intelligent Electronic Device.

Therefore, further improvements to Intelligent Electronic Devices would be desirable.

### SUMMARY OF THE INVENTION

The embodiments of the present disclosure generally relate to the method and apparatus for measuring frequency within any electrical power distribution system.

In some embodiments, the present disclosure provides an Intelligent Electronic Device. The Intelligent Electronic Device includes at least one sensor configured for sensing at least one electrical parameter of electrical power distributed from an electrical distribution system to a load; at least one analog-to-digital converter coupled to the at least one sensor and configured for converting an analog signal output from the at least one sensor to digital data; at least one processing module coupled to the at least one analog-to-digital converter, wherein the at least one processing module is configured to receive a training dataset including an input variable set and a corresponding zero-crossing position output variable; obtain a hypothesis function based on the training dataset; estimate zero-crossing positions using the hypothesis function; compute a fundamental frequency of a power line signal based on the estimated zero-crossing positions.

In some other embodiments, the present disclosure provides a method for estimating a fundamental frequency of a power line signal in an electrical power distribution system. The method includes providing a training dataset including an input variable set and a corresponding zero-crossing position output variable; obtaining a hypothesis function based on the training dataset; estimating zero-crossing positions using the hypothesis function; computing a fundamental frequency of a power line signal based on the estimated zero-crossing positions.

In some other embodiments, the present disclosure provides a method for estimating a RMS (Root Mean Square) voltage of a power line signal in an electrical power distribution system. The method includes providing a training dataset including an input variable set and a corresponding zero-crossing position output variable; obtaining a hypothesis function based on the training dataset; estimating zero-crossing positions using the hypothesis function; computing a RMS (Root Mean Square) voltage of a power line signal based on the estimated zero-crossing positions.

These and other features and aspects of the present disclosure can become fully apparent from the following detailed description of exemplary embodiments, the appended claims and the accompanying drawings.

### BRIEF DESCRIPTION OF THE DRAWINGS

FIG. 1 is a block diagram of an exemplary Intelligent Electronic Device.

FIG. 2 is a flow chart depicting an example method embodiment according to some aspects of the present disclosure.

FIG. 3 is an example graph depicting an exemplary frequency calculation of an example embodiment according to some aspects of the present disclosure.

FIG. 4 is another flowchart depicting an example method embodiment according to some aspects of the present disclosure.

FIG. 5 is an example graph depicting exemplary RMS voltage calculation of an example embodiment according to some aspects of the present disclosure.

### DETAILED DESCRIPTION

Embodiments of the present disclosure can be described herein with reference to the accompanying drawings. In the following descriptions, well-known functions or constructions are not described in detail to avoid obscuring the present disclosure. The word “exemplary” may be used herein to mean “serving as an example.” Any configuration or design described herein as “exemplary” may not be to be constructed as preferred, or advantageous, over other configurations or designs. Herein the phrase “coupled” may be defined as “directly connected to or indirectly connected with” one or more intermediate components. Such intermediate components may include both hardware and software-based components.

It may further be noted that, unless otherwise indicated, all functions described herein may be implemented in either software, hardware, or some combination thereof.

It should be recognized that the present disclosure can be performed in numerous ways, including as a process, an apparatus, a system, a method, or a computer-readable medium such as a computer storage medium.

As used herein, Intelligent Electronic Devices can be any device that can sense electrical parameters and can compute data including, but not limited to, Programmable Logic Controllers (“PLCs”), Remote Terminal Units (“RTUs”), electrical power meters, protective relays, fault recorders, phase measurement units, and other devices which can be coupled with power distribution networks to control and manage the distribution or consumption of electrical power.

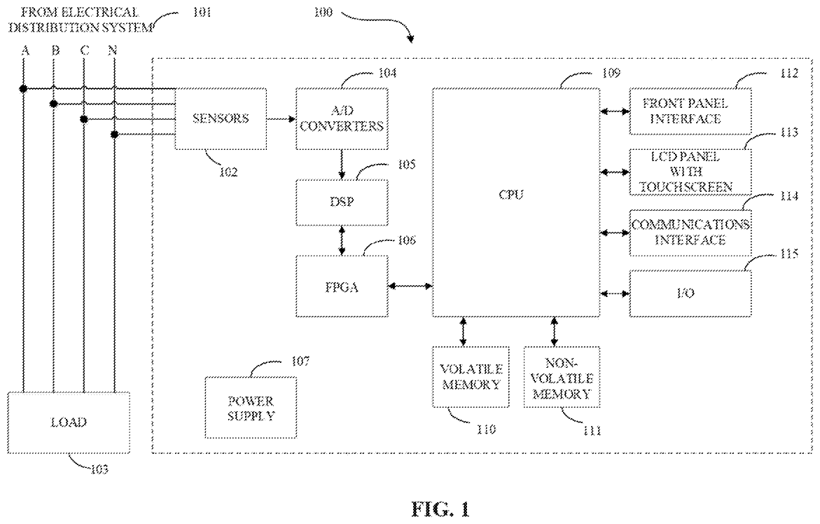

FIG. 1 is an exemplary block diagram of an Intelligent Electronic Device 100 for monitoring power usage and power quality for any metered point within a power distribution system.

The Intelligent Electronic Device 100 illustrated in the exemplary embodiment of FIG. 1 can include multiple sensors 102 which may be coupled with various phases A, B, C, and N (neutral) of an electrical distribution system 101, multiple analog-to-digital (A/D) converters 104, a power supply 107, volatile memory 110, non-volatile memory 111, a front panel interface 112, and a processing module that can include at least one Central Processing Unit (CPU) and/or one or more Digital Signal Processors (DSP), two of which are shown DSP 105 and CPU 109. The Intelligent Electronic Device 100 can also include a Field Programmable Gate Array (FPGA) 106 which can perform several functions which can include acting as a communications bridge for transferring data between the various processors (105 and 109).

The sensors 102 can sense electrical parameters, such as voltage and current, on incoming lines (phase A, phase B, phase C, and neutral N) of an electrical power distribution system 101 which may be coupled to at least one load 103 that consumes the provided power. In one embodiment, the sensors 102 can include current transformers and potential transformers, where one current transformer and one voltage transformer can be coupled to each phase of the incoming power lines. The primary winding of each transformer can be coupled to the incoming power lines, and the secondary winding of each transformer can output a voltage representative of the sensed voltage and current. The output of each transformer can be coupled with the A/D converters 104, which can be configured to convert the analog voltage output from the transformer to a digital signal that can be processed by the DSP 105.

A/D converters 104 can be configured to convert an analog voltage output to a digital signal that may be transmitted to a gate array, such as Field Programmable Gate Array (FPGA) 106. The digital signal can then be transmitted from the FPGA 106 to the CPU 109.

The CPU 109 or DSP Processors 105 can be configured to receive digital signals from the A/D converters 104 and perform the necessary calculations to determine power usage and control the overall operations of the Intelligent Electronic Device 100. In some embodiments, the CPU 109 and DSP 105 may be combined into a single processor to serve the functions of each component. In some embodiments, it may be contemplated to use an Erasable Programmable Logic Device (EPLD), a Complex Programmable Logic Device (CPLD), or any other programmable logic device in place of the FPGA 106. In some embodiments, the digital samples, which can be output from the A/D converters 104, can be sent directly to the CPU 109, effectively bypassing the DSP 105 and the FPGA 106 as a communications gateway.

The power supply 107 provides power to each component of the Intelligent Electronic Device 100. In one embodiment, the power supply 107 may be a transformer with its primary windings which may be coupled to the incoming power distribution lines to provide a nominal voltage at its secondary windings. In other embodiments, power may be supplied from an independent power source to the power supply 107.

In the exemplary embodiment of FIG. 1, the front panel interface 112 is shown coupled to the CPU 109, which can include indicators, switches, and various inputs.

In the exemplary embodiment of FIG. 1, the LCD panel with touchscreen 113 is shown coupled to the CPU 150 for interacting with a user and for communicating events, such as alarms and instructions. The LCD panel with touchscreen 113 may provide information to the user in the form of alpha-numeric lines, computer-generated graphics, videos, animations, etc.

An Input/Output (I/O) interface 115 may be provided for receiving externally generated inputs from the Intelligent Electronic Device 100 and for outputting data, such as serial data, to other devices. In one embodiment, the I/O interface 115 may include a connector for receiving various cards and/or modules that increase and/or change the functionality of the Intelligent Electronic Device 100. In a further embodiment, the I/O interface 115 may include digital output for energy pulse.

The Intelligent Electronic Device 100 can also include volatile memory 110 and non-volatile memory 111. The volatile memory 110 can store the sensed and generated data for further processing and for retrieval when requested to be displayed at the Intelligent Electronic Device 100 or from a remote location. The volatile memory 110 can include internal storage memory, such as Random-Access Memory (RAM). The non-volatile memory 111 can include removable memory, such as magnetic storage memory, optical storage memory (such as various types of CD or DVD media), solid-state storage memory, (such as a CompactFlash card, a Memory Stick, SmartMedia card, MultiMediaCard [MMC], SD [Secure Digital] memory), or any other memory storage that exists currently or can exist in the future. Such memory can be used for storing historical trends, waveform captures, event logs (including timestamps), and stored digital samples for later download to a client application, webserver, or PC application.

In a further embodiment, the Intelligent Electronic Device 100 can include a communication interface 114, also known as a network interface, for enabling communications between the Intelligent Electronic Device, or meter, and a remote terminal unit or programmable logic controller and other computing devices, microprocessors, desktop computers, laptop computers, other meter modules, etc. The communication interface 114 may be a modem, Network Interface Card (NIC), wireless transceiver, or another interface. The communication interface 114 can operate with hardwired and/or wireless connectivity. A hardwired connection may include, but may not be limited to, physical cabling (such as parallel cables serial cables, RS232, RS485, USB cables, or Ethernet) and an appropriately configured communication port. The wireless connection may operate under any of the various wireless protocols including, but not limited to, Bluetooth™ interconnectivity, infrared connectivity, radio transmission connectivity (including computer digital signal broadcasting and reception commonly referred to as Wi-Fi or 802.11.X [where x denotes the type of transmission]), satellite transmission, or any other type of communication protocol, communication architecture, or systems currently existing or to be developed for wirelessly transmitting data.

The Intelligent Electronic Device 100 may communicate to a server or other computing device via the communication interface 114. The Intelligent Electronic Device 100 may be connected to a communications network (such as the Internet) by any means. For example, a hardwired or wireless connection, such as dial-up, hardwired, cable, DSL, satellite, cellular, PCS, or wireless transmission (e.g., 802.11a/b/g) may be used. It is noted that the network may be a Local Area Network (LAN), Wide Area Network (WAN), the Internet, or any network that couples multiple computers to enable various modes of communication via network messages. Furthermore, the server can communicate using various protocols, such as Transmission Control Protocol/Internet Protocol (TCP/IP), File Transfer Protocol (FTP), or Hypertext Transfer Protocol (HTTP) or via secure protocols such as Hypertext Transfer Protocol Secure (HTTPS), Internet Protocol Security Protocol (IPSec), Point-to-Point Tunneling Protocol (PPTP), Secure Sockets Layer (SSL) Protocol, or via other secure protocol. The server may further include a storage medium for storing the data received from at least one Intelligent Electronic Device or meter and/or storing data to be retrieved by the Intelligent Electronic Device or meter.

In an additional embodiment, when a power event occurs, such as a voltage surge, voltage sag, or current short circuit, the Intelligent Electronic Device 100 may also have the capability of not only digitizing waveforms but storing the waveform and transferring that data upstream to a central computer, such as a remote server. The power event may be captured, stored to memory (e.g., non-volatile RAM), and additionally transferred to a host computer within the existing communication infrastructure either immediately, in response to a request from a remote device or computer, or later in response to a polled request. The digitized waveform can also allow the CPU 109 to compute other electrical parameters such as harmonics, magnitudes, symmetrical components, and phasor analysis.

In a further embodiment, the Intelligent Electronic Device 100 can execute an e-mail client and can send notification e-mails to the utility or directly to the customer when a power quality event occurs. This can allow utility companies to dispatch crews to repair the condition. The data generated by the meters may be used to diagnose the cause of the condition. The data may be transferred through the infrastructure created by the electrical power distribution system. The e-mail client can utilize POP3 or another standard e-mail protocol.

The techniques of the present disclosure can be used to automatically maintain program data and provide field-wide updates upon which Intelligent Electronic Device firmware and/or software can be upgraded. An event command can be issued by a user, on a schedule, or through a digital communication that can trigger the Intelligent Electronic Device 100 to access a remote server and obtain the new program code. This can ensure that program data can be maintained, assuring the user that all information can be identically displayed on all units.

It is to be understood that the present disclosure may be implemented in various forms of hardware, software, firmware, special purpose processors, or a combination thereof. The Intelligent Electronic Device 100 can also include an operating system and application programs. The various processes and functions described herein may either be part of an application program (or a combination thereof) which can be executed via the operating system.

Because some of the system components and methods depicted in the accompanying figures may be implemented using either software or firmware, it is to be further understood that the actual connections between the system components (or the process steps) may differ depending on the specific way the present disclosure is programmed. Given the teachings of the present disclosure provided herein, one of ordinary skill in the related art can be able to contemplate these and similar implementations or configurations of the present disclosure.

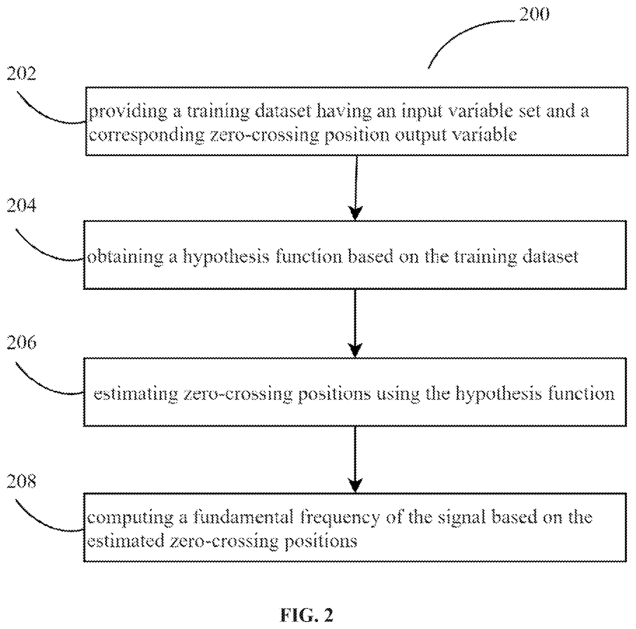

The exemplary embodiment of FIG. 2 illustrates a method 200 for line frequency estimation in an Intelligent Electronic Device 100. In the first step 202, the Intelligent Electronic Device 100 provides a training dataset which can include an input variable set and a corresponding zero-crossing position output variable. In an embodiment, the training dataset may be stored in the non-volatile memory 111. The training dataset may be read by DSP 105 for further processing when necessary.

A training dataset can be a dataset of training examples used during the learning process and can be used to fit the parameters of a model. The training dataset may be used in supervised learning. Supervised learning can be the machine learning task of inferring a function from labelled training data. The training examples consist of an input vector (feature ‘X’) and its associated correct output value (‘Y’).

Various algorithms and computation techniques may be used in the supervised machine learning processes such as neural networks, polynomial regression, etc. The following describes polynomial regression as an example.

Polynomial regression can be a form of regression analysis in which the relationship between the independent variable x and the dependent variable y can be modelled as an nth degree polynomial in x.

Table 1 shows an exemplary training dataset for the third-order polynomial regression approach for zero-crossing estimation, assuming ‘m’ training examples are available. In table 1, X represents the detected zero-crossing positions of an electrical signal, and Y represents the actual zero-crossing position of an electrical signal.

TABLE 1

| m | | | | Y |
|---|---|---|---|---|
| (number of | | | | (actual zero- |
| training | X | X² | X³ | crossing |
| examples) | (feature 1) | (feature 2) | (feature 3) | position output) |
| 1 | 1.25 | 1.56 | 1.95 | 1.24 |
| 2 | 2.31 | 5.33 | 12.33 | 2.32 |
| . . . | . . . | . . . | . . . | . . . |
| m | 5.56 | 30.91 | 171.88 | 5.58 |

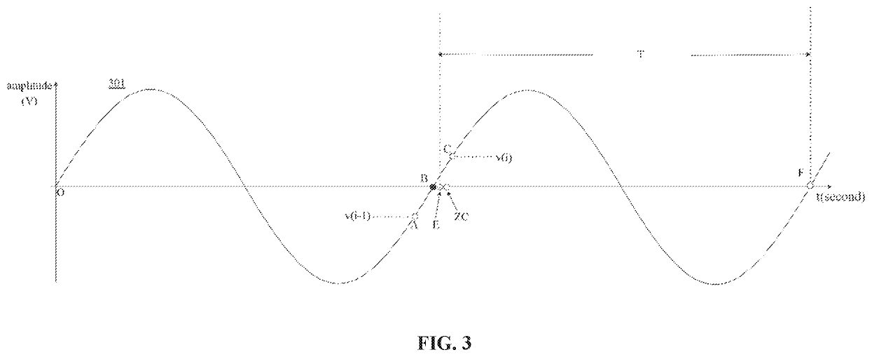

FIG. 3 can now be discussed, which depicts an exemplary frequency calculation of an example embodiment of the present disclosure. The electrical signal 501 may be sensed by sensors 102 from one of the various phases A, B, C, and N (neutral) of an electrical distribution system 101. The x-axis represents time in seconds. The y-axis represents the amplitude of electrical signal 301 in volts. Detected zero-crossing position ZC can be computed with interpolation that may be based upon the following equation:

$$ZC = i - \frac{v ( i )}{v ( i ) - v ( i - 1 )} ,$$

wherein ‘i’ represents an index number of the digital samples; v(i) represents a voltage of a digital sample C disposed immediately after ZC; and v(i−1) represents a voltage of a digital sample A disposed immediately before ZC. B can be the actual zero-crossing. The detected zero-crossing position ZC may be computed by DSP 105.

A set of actual zero-crossing positions and detected zero-crossing positions would be collected as a training dataset. The square and cube of detected zero-crossing positions would also be calculated as a training dataset in table 1.

In step 204, the Intelligent Electronic Device 100 can obtain a hypothesis function that may be based on the training dataset. After DSP 105 receives the training dataset, it can deduce a hypothesis that may be based on the training dataset.

The task of supervised learning can be to analyze the training data and come up with a hypothesis function h_{θ}(x) which can be used for mapping data in the field.

In this disclosure, the task of such a supervised learning method can be to create a hypothesis function h_{θ}(x) that accurately estimates a zero-crossing position that may be based on a training dataset made up of selected input vector “features X” and their corresponding output (y).

In an embodiment, the hypothesis function h_{θ}(x) can be deduced using a multivariate polynomial regression approach.

According to a preferred embodiment, a third-order polynomial can be used. Different order polynomials may be used apart from the proposed third-order polynomial if better accuracy in the estimations can be obtained. The accuracy depends on the training dataset.

In a further embodiment, the hypothesis function (h_{θ}(X)) can be defined as a function of the input variable set “feature X” (X=[X₀ X₁ X₂ . . . Xₙ]) and the parameters (θ=[θ₀ θ₁ θ₂ θ₃]).

h_{θ}(X)=θ₀+θ₁X+θ₂X²+θ₃X³

Wherein the theta parameters (θ=[θ₀ θ₁ θ₂ θ₃]) are real numbers determined from a cost function (J(θ)) by iteratively adjusting the theta parameters (θ=[θ₀ θ₁ θ₂ θ₃]) to minimize the cost function (J(θ)) using an optimization algorithm.

The theta parameters (θ=[θ₀ θ₁ θ₂ θ₃]) are learned by the regression algorithm to minimize the error between the actual value ‘y’ and the algorithm estimated value h_{θ}(x).

The goal of the polynomial regression can be to iteratively adjust the theta parameters (θ=[θ₀ θ₁ θ₂ θ₃]) in order to minimize the cost function J(θ) defined as the average square error using an optimization algorithm. The cost function can be defined as follows:

$$J ( θ ) = \frac{1}{2 m} [ {\sum }_{i = 1}^{m} {( {h}_{θ} ( {x}^{( i )} ) - {y}^{i} )}^{2} + λ {\sum }_{i = 1}^{n} {θ}_{j}^{2} ] ,$$

wherein ‘m’ is the number of training examples, ‘λ’ is the regularization parameter which can be adjusted to avoid overfitting problems and ‘n’ is the number of “feature X”.

In step 206, the Intelligent Electronic Device 100 can estimate zero-crossing positions using the hypothesis function. For example, after the DSP 105 obtains the detected zero-crossing positions, DSP 105 can estimate zero-crossing positions using the hypothesis function h_{θ}(X). In the exemplary embodiment of FIGS. 3, E and F can be the consecutive estimated zero-crossing positions.

In step 208, the Intelligent Electronic Device 100 can compute a fundamental frequency of a signal that may be based on the estimated zero-crossing positions. For example, DSP 105 may get a fundamental frequency by calculating the interval between two consecutive estimated zero-crossings. In FIG. 3, T_{EF} is the interval between two consecutive estimated zero-crossings E and F. The fundamental frequency f can be calculated as follows:

f=1/T_{EF}.

The fundamental frequency computed from step 208 may be displayed on the LCD panel with touchscreen 113. When the fundamental frequency measured reaches a pre-determined threshold, the IED 100 can execute an e-mail client and can send notification e-mails to the utility or directly to the customer.

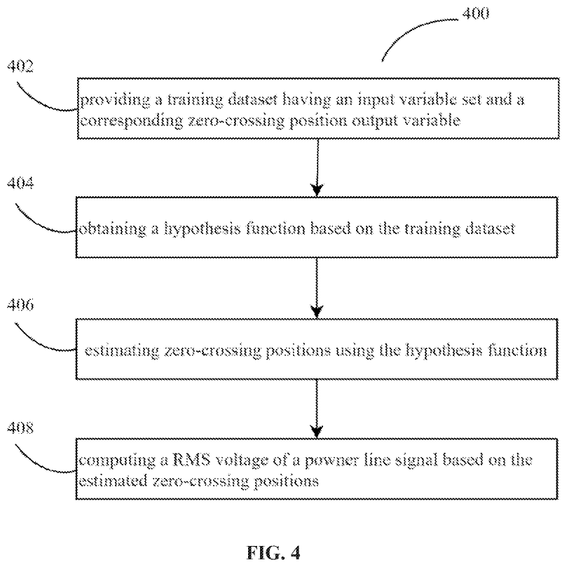

FIG. 4 illustrates an exemplary method 400 for RMS (Root Mean Square) voltage estimation in an Intelligent Electronic Device 100. Since method 400 may be similar to method 200, the same part can be described in short.

In the first step 402, the Intelligent Electronic Device 100 can provide a training dataset having an input variable set and a corresponding zero-crossing position output variable. In an embodiment, the training dataset may be stored in the non-volatile memory 111. The training dataset may be read by DSP 105 for further processing when necessary.

In step 404, the Intelligent Electronic Device 100 can obtain a hypothesis function that may be based on the training dataset. After DSP 105 receives the training dataset, it can deduce a hypothesis that may be based on the training dataset.

In step 406, the Intelligent Electronic Device 100 can estimate zero-crossing positions using the hypothesis function. For example, after the DSP 105 obtains the detected zero-crossing positions, the DSP 105 can estimate zero-crossing positions using the hypothesis function h_{θ}(X).

In step 408, the Intelligent Electronic Device 100 can compute a RMS (Root Mean Square) voltage of a power line signal that may be based on the estimated zero-crossing positions. DSP 105 may get a RMS voltage Vₘₛ by the following equation:

$${V}_{rms} = \sqrt{\frac{1}{N} {\sum }_{i = 0}^{N - 1} {V}_{pi}^{2}}$$

Where ‘N’ represents the number of samples in one full zero-crossing cycle, Vₚᵢ represents i^{th} phase voltage.

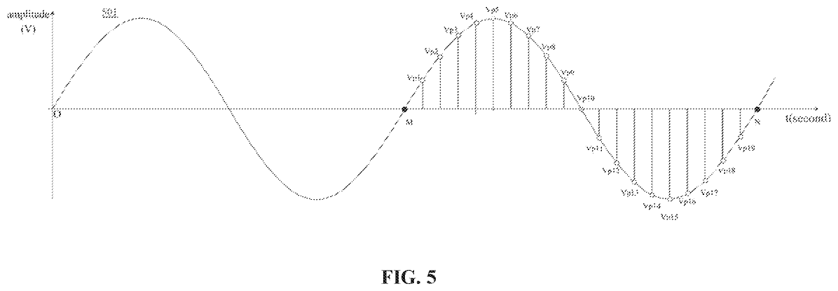

FIG. 5 will now be discussed, which depicts exemplary RMS voltage calculation of an example embodiment of the present disclosure. The electrical signal 501 may be sensed by sensors 102 from various phases A, B, C, and N (neutral) of an electrical distribution system 101. The x-axis represents time in seconds. The y-axis represents the amplitude of electrical signal 301 in volts. M and N can be the consecutive zero-crossing positions estimated by the Intelligent Electronic Device 100 from step 406. After the estimated zero-crossing positions are determined, 19 samples can be selected by DSP 105. The RMS voltage Vₘₛ can be calculated based on the phase voltages Vₚ₁-Vₚ₁₉ from 19 samples.

The RMS voltage computed from step 408 may be displayed on the LCD panel with touchscreen 113. When the RMS voltage reaches a pre-determined threshold, the IED 100 can execute an e-mail client and can send notification e-mails to the utility or directly to the customer.

Embodiments of the teachings of the present disclosure have been described in an illustrative manner. It is to be understood that the terminology that has been used, may be intended to be in the nature of words of description rather than of limitations. Many modifications and variations of the embodiments are possible in light of the above teachings. Therefore, within the scope of the appended claims, the embodiments can be practiced other than specifically described.

What is claimed is:

1. A method of measuring frequency in an Intelligent Electronic Device, the method comprising:
providing a training dataset including an input variable set and a corresponding zero-crossing position output variable;
obtaining a hypothesis function based on the training dataset;
estimating zero-crossing positions using the hypothesis function;
computing a fundamental frequency of a power line signal based on the estimated zero-crossing positions.

2. The method of claim 1 further comprising deriving the input variable set from detected zero-crossing positions of an electrical signal using a digital signal processor (DSP) within an Intelligent Electronic Device.

3. The method of claim 1 further comprising deducing the hypothesis function using a multivariate polynomial regression approach.

4. The method of claim 3, wherein the hypothesis function is defined as a function of the input variable set X=[X₀ X₁ X₂ . . . Xₙ] and the theta parameters θ=[θ₀ θ₁ θ₂ θ₃] given by h_{θ}(X)=θ₀+θ₁X+θ₂X²+θ₃X³,
wherein the theta parameters θ=[θ₀ θ₁ θ₂ θ₃] are real numbers determined from a cost function by iteratively adjusting the theta parameters to minimize the cost function using an optimization algorithm.

5. The method of claim 4, wherein the optimization algorithm is a gradient descent algorithm.

6. The method of claim 2, wherein the detected zero-crossing position is determined by interpolating a pair of digital samples with each one disposed on either side of the detected zero-crossing.

7. The method of claim 6, wherein interpolating a pair of digital samples includes computing a first zero-crossing based upon the following equation:
ZC=i−v(i)/v(i)−v(i−1),
wherein ZC represents the first zero-crossing position in time; i represents an index number of the digital samples; v(i) represents a voltage of a digital sample disposed immediately after the first zero-crossing position; and v(i−1) represents a voltage of a digital sample disposed immediately before the first zero-crossing position.

8. An intelligent electronic device (IED) comprising:
at least one sensor configured for sensing at least one electrical parameter of electrical power distributed from an electrical distribution system to a load;
at least one analog-to-digital converter coupled to the at least one sensor and configured for converting an analog signal output from the at least one sensor to digital data; and
at least one processing module coupled to the at least one analog-to-digital converter, wherein the at least one processing module is configured to:
receive a training dataset including an input variable set and a corresponding zero-crossing position output variable;
obtain a hypothesis function based on the training dataset;
estimate zero-crossing positions using the hypothesis function; and
compute a fundamental frequency of a power line signal based on the estimated zero-crossing positions.
